(19) United States
(12) Patent Application Publication
(10) Pub. No.: US 2012/0292673 A1
(43) Pub. Date: Nov. 22, 2012

(54) Semiconductor Device and Manufacturing Method Thereof

(75) Inventor: Weizhong Xu, Shanghai (CN)

(73) Assignee: SEMICONDUCTOR MANUFACTURING INTERNATIONAL (SHANGHAI) CORPORATION, Shanghai (CN)

(21) Appl. No.: 13/325,021

(22) Filed: Dec. 13, 2011

(30) Foreign Application Priority Data
May 20, 2011 (CN) 201110131064.1

(51) Int. Cl. H01L 29/78; H01L 21/336

(52) U.S. Cl. 257/288; 438/303; 257/E21.409; 257/E29.255

(57) ABSTRACT

A semiconductor device and manufacture method thereof is disclosed. The method includes: forming a gate on a substrate; forming a stack including a first material layer, a second material layer, and a third material layer from inner to outer in sequence; etching the stack to form sidewall spacers on opposite sidewalls of the gate; performing ion implantation to form a source region and a drain region; partially or completely removing the remaining portion of the third material layer; performing a pre-cleaning process, wherein all or a portion of the remaining portion of the second material layer is removed; forming silicide on top of the source region, the drain region, and the gate; depositing a stress film to cover the silicide and the remaining portion of the first material layer. According to the above method, the stress proximity technique (SPT) can be realized while avoiding silicide loss.

### CROSS-REFERENCE TO RELATED APPLICATIONS

This application claims priority to Chinese Patent Application No. 201110131064.1, filed on May 20, 2011 and entitled “SEMICONDUCTOR DEVICE AND MANUFACTURING METHOD THEREOF”, which is incorporated herein by reference in its entirety.

### BACKGROUND OF THE INVENTION

1. Field of the Invention

The present invention relates to semiconductor techniques, and more particularly to semiconductor devices and manufacture methods thereof.

2. Description of the Related Art

With the increasing development of semiconductor techniques, MOSFET feature size is continually reduced, drawing tremendous attention in the field to the issue of carrier mobility reduction, and consequently leading to several schemes of carrier mobility enhancement.

Some of such schemes realize carrier mobility enhancement through applying stress to MOSFET channel region.

Through applying stress to the channel region of MOS device to induce strains in the channel region, it is possible to influence the carrier mobility in the channel region. Specifically, NMOS device is electron conductive, the larger the lattice spacing is, the smaller the effects of lattice scattering, and thus, a larger the electron mobility, as well as a driving current, can be achieved, therefore, it is desirable to apply a tensile stress to the channel to enlarge the crystal lattice; for PMOS device, on the contrary, the smaller the lattice spacing is, the larger the hole mobility is, so it is desirable to apply a compressive stress to the channel.

A method of applying stress to channel region is the covering film stress technique.

Depositing a stress film after forming silicide on source, drain and gate regions, a stress can be transmitted to the channel region, so that the device performance can be significantly affected. As an example of stress film, it is known that Si₃N₄ film deposited by thermal chemical vapor deposition has tensile stress, while Si₃N₄ film deposited by plasma chemical vapor deposition has compressive stress.

In order to improve NMOS and PMOS device performance simultaneously, tensile and compressive stress films can be deposited on NMOS and PMOS devices respectively. For example, first, a tensile stress film can be deposited, and then it can be etched to remove the tensile stress film covering a PMOS device, and then a compressive stress film can be deposited, followed by removing the compressive stress film on a NMOS device.

A stress proximity technique (SPT) is set forward to transmit stress into a channel region more successfully. That is, a sidewall spacer on opposite sides of the gate is reduced in thickness before stress film deposition to shorten the distance between the stress film and the channel region, so that the stress in the stress film can be transmitted into the channel region more effectively. Consequently, a better effect can be achieved.

Next, a SPT implementation method will be described with reference of FIGS. 1A to 1E.

First, as shown in FIG. 1A, after performing lightly doped region (LDD) implantation on the substrate 10 using the gate as a mask, a silicon oxide layer 30 which is relatively thinner and a silicon nitride layer 40 which is relatively thicker are deposited in sequence.

Next, as shown in FIG. 1B, the silicon oxide layer 30 and the silicon nitride layer 40 are etched to form sidewall spacers 50 including the remaining silicon oxide portion 35 and the remaining silicon nitride portion 45 on the sidewalls of the gate, after which source-drain implantation is implemented.

Next, as shown in FIG. 1C, a metal such as Ni or Pt is deposited on the source region, the drain region and the gate. A silicide forming process is performed to form silicide 60.

Next, as shown in FIG. 1D, the silicon nitride portion 45 is removed by etching.

Then, as shown in FIG. 1E, a stress film 70 is deposited thereon.

Since the thicker silicon nitride portion 45 is removed after defining the source and drain regions with the spacer 50, the stress film 70 is placed more proximately to the channel region, such that the stress in the stress film can be transmitted into the channel region more effectively.

As shown in FIG. 1D, however, when removing the silicon nitride portion 45, the silicide 60 formed previously may have a loss. Therefore, it is required to form more silicide as compared to those solutions without the above scheme.

Hence, a new SPT implementation method capable of avoiding silicide loss is highly desired.

### BRIEF SUMMARY OF THE INVENTION

An aspect of this invention is to provide a method of manufacturing semiconductor devices, which can avoid silicide loss while realizing the stress proximity technique.

According to one aspect of this invention, a method of manufacturing a semiconductor device is provided, which may comprise the following steps: forming a gate on a substrate; forming a stack including a first material layer, a second material layer, and a third material layer from inner to outer in sequence, to cover the surface of the substrate, the top surface of the gate, and opposite sidewalls of the gate; etching the stack to form sidewall spacers on opposite sidewalls of the gate, including the remaining portions of the first material layer, the second material layer and the third material layer; performing ion implantation to form a source region and a drain region on opposite sides of the gate respectively; partially or completely removing the remaining portion of the third material layer; performing a pre-cleaning process, wherein all or a portion of the remaining portion of the second material layer is removed; forming silicide on top of the source region, the drain region and the gate; depositing a stress film to cover the silicide and the remaining portion of the first material layer.

Preferably, the remaining portion of the second material layer serves as a block layer when partially or completely removing the remaining portion of the third material layer.

Preferably, the step of partially or completely removing the remaining portion of the third material layer may be implemented through a wet or dry etching process with a high selectivity ratio to the second material layer.

Preferably, each of the first material layer and the third material layer may be a silicon nitride layer or a silicon oxynitride layer, and the second material layer may be a silicon oxide layer.

Preferably, the stack may further comprise an oxide layer under the first material layer; the sidewall spacers may further comprise a remaining portion of the oxide layer; when performing the pre-cleaning process, the remaining portion of the first material layer serves as a block layer to prevent the oxide layer from being removed.

Preferably, the oxide layer may be a silicon oxide layer.

Preferably, when the channel region is n-type channel region, the stress film may be a tensile stress film.

Preferably, when the channel region is p-type channel region, the stress film may be a compressive stress film.

According to another aspect of this invention, a semiconductor device is provided, which may comprise: a gate on a substrate; a source region and a drain region respectively on opposite sides of the gate; silicide on top of the source region, the drain region, and the gate; an “L”-shaped first material layer located between the gate and the silicide on top of the source region, between the gate and the silicide on top of the drain region, and on the sidewalls of the gate, the first material having a lower selectivity ratio than an oxide in a pre-cleaning operation prior to the silicide forming process; and a stress film covering the silicide and the “L”-shaped first material layer.

Preferably, the first material may be silicon nitride or silicon oxynitride.

Preferably, the semiconductor device may further comprise an “L”-shaped silicon oxide layer located between the “L”-shaped first material layer and the substrate, and between the “L”-shaped first material layer and the sidewalls of gate.

Preferably, the gate is adjacent to a channel region, and when the channel region is an n-type channel region, the stress film is a tensile stress film.

Preferably, the gate is adjacent to a channel region, and when the channel region is a p-type channel region, the stress film is a compressive stress film.

With the method disclosed above, silicide loss can be avoided while improving device performance through SPT.

### BRIEF DESCRIPTION OF THE DRAWINGS

The accompanying drawings illustrate embodiments of the invention and, together with the description, serve to explain the principles of the invention.

It should be noted that in those drawings those parts are not illustrated in actual proportion for the convenience of description.

FIGS. 1A-1E respectively illustrate in sectional views each step of one implementation of the stress proximity technique in prior art;

FIGS. 2A-2F respectively illustrate in sectional views each step of one implementation of the method of manufacturing a semiconductor device according to this invention; and

FIGS. 3A-3F respectively illustrate in sectional views each step of another implementation of the method of manufacturing a semiconductor device according to this invention.

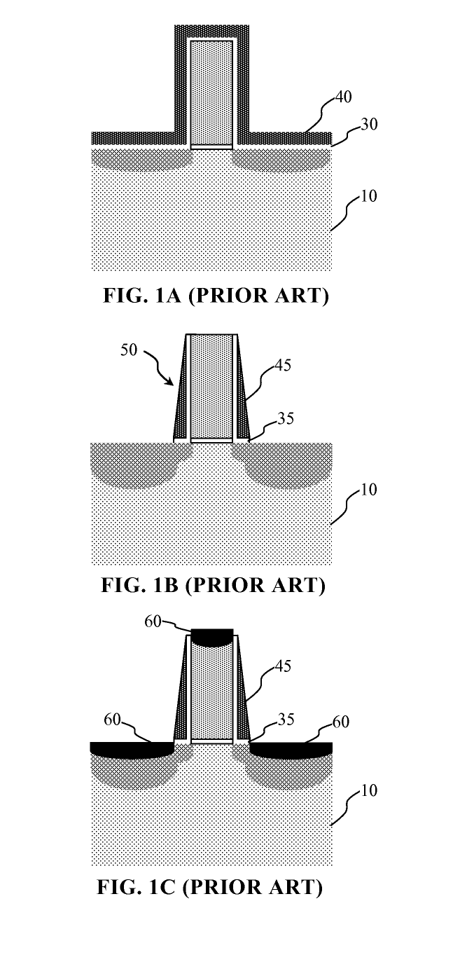

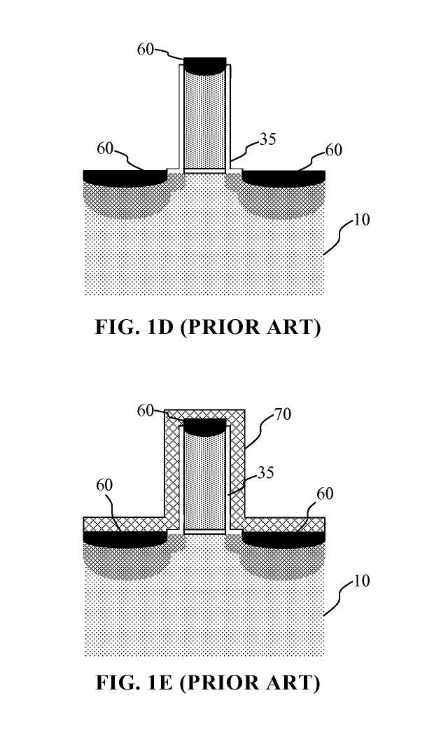

### DETAILED DESCRIPTION OF THE INVENTION

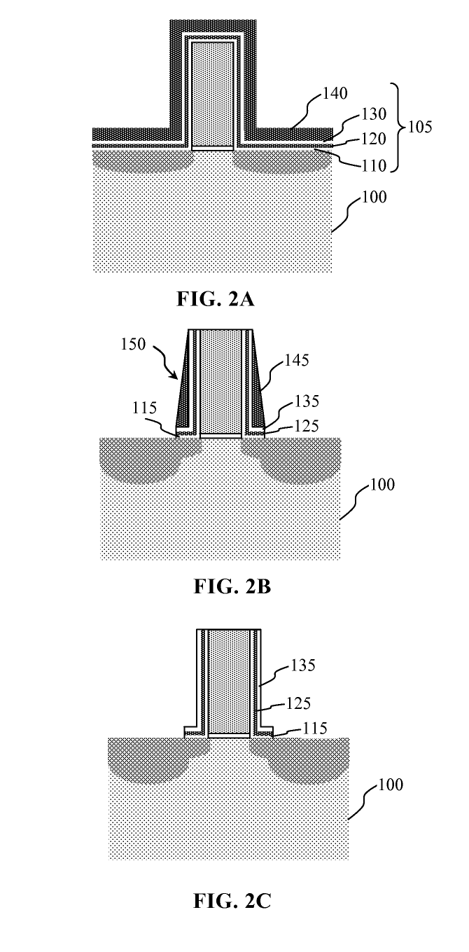

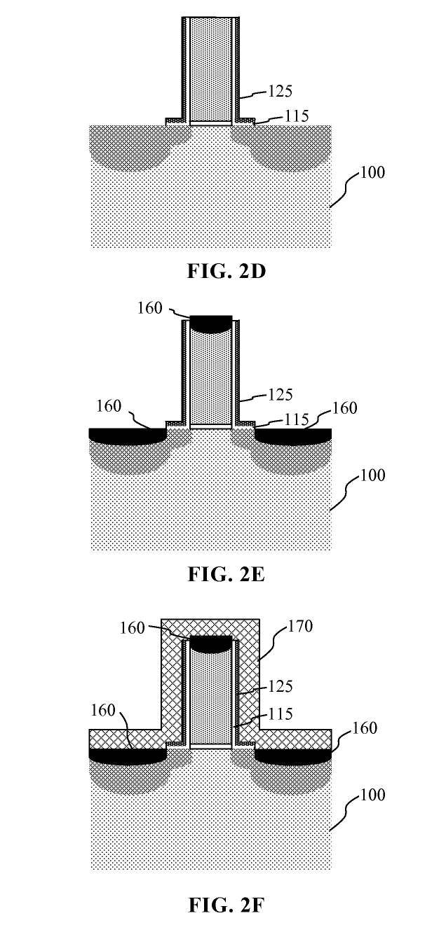

Next, an implementation of the method of manufacturing a semiconductor device will be described with reference to FIGS. 2A-2F.

First, as shown in FIG. 2A, a gate is formed on a substrate 100. The substrate 100 may comprise Si, and preferably have a (100) crystal plane. The gate is adjacent to a channel region. e.g., the gate can be located above the channel region. Upon performing lightly doped region (LDD) implantation using the gate as a mask, a first oxide layer 110, a first nitride layer 120, a second oxide layer 130 and a second nitride layer 140 are deposited in sequence to form a stack 105. The stack 105 covers the surface of the substrate 100, the top surface of the gate, and opposite sidewalls of the gate.

The second nitride layer 140 may be relatively thicker, while the first oxide layer 110, the first nitride layer 120, and the second oxide layer 130 may be relatively thinner. The first oxide layer 110 and the second oxide layer 130 may be silicon oxide layers, while the first nitride layer 120 and the second nitride layer 140 may be silicon nitride layers.

Either or both of the first nitride layer 120 and the second nitride layer 140 can also be substituted with an oxynitride layer, for example, a silicon oxynitride layer.

Next, as shown in FIG. 2B, the stack 105 is etched to form sidewall spacers 150 on the sidewalls of the gate. The sidewall spacers 150 comprise the remaining portion 115 of the first oxide layer 110, the remaining portion 125 of the first nitride layer 120, the remaining portion 135 of the second oxide layer 130, and the remaining portion 145 of the second nitride layer 140. Then, ions are implanted to form source region and drain region on opposite sides of the gate respectively.

Next, as shown in FIG. 2C, all or a portion of the remaining portion 145 of the second nitride layer 140 is removed through a wet or dry etching process with a high selectivity ratio to the remaining portion 135 of the second oxide layer 130. By doing so, the remaining portion 135 of the second oxide layer 130 serves as a block layer to prevent the remaining portion 125 of the first nitride layer 120 and the remaining portion 115 of the first oxide layer 110 from being removed.

Next, as shown in FIG. 2D, a pre-cleaning process is performed before the formation of silicide. In the pre-cleaning process, the oxides on the surfaces of the source region, the drain region and the gate are removed. Meanwhile, all or a portion of the remaining portion 135 of the second oxide layer 130 is also removed.

The remaining portion 125 of the first nitride layer 120 is not removed in the pre-cleaning process, which in turn can preserve the remaining portion 115 of the first oxide layer 110.

Next, as shown in FIG. 2E, silicide 160 is formed on top of the source region, the drain region, and gate. For example, a metal such as Ni or Pt is deposited. And then, a silicide forming process is performed to form metal silicides.

Next, as shown in FIG. 2F, a stress film 170 is deposited to cover the silicide 160 and the remaining portion 125 of the first nitride layer 120 (as well as two exposed ends of the remaining portion 115 of the first oxide layer 110).

For a NMOS device region with n-type channel, a tensile stress film is deposited, and for a PMOS device region with p-type channel, a compressive stress film is deposited.

As an example of the stress film, a Si₃N₄ film deposited through thermal chemical vapor deposition can be utilized as the tensile stress film, and a Si₃N₄ film deposited through plasma chemical vapor deposition can be utilized as the compressive stress film. However, the present invention is not limited to that example.

As shown in FIG. 2F, the semiconductor device manufactured by the above method comprises: a gate on a substrate 100; a source region and a drain region respectively on opposite sides of the gate; silicide 160 on top of the source region, the drain region and the gate; an “L”-shaped oxide layer extending between the gate and the silicide 160 on top of the source region, between the gate and the silicide 160 on top of the drain region, and on the gate sidewalls (the remaining portion 115 of the first oxide layer 110); an “L”-shaped nitride layer on top of the “L”-shaped oxide layer 115 (the reminding portion 125 of the first nitride layer 120); and a stress film 170 covering the silicide 160, the “L”-shaped oxide layer 115 and the “L”-shaped nitride layer 125.

As mentioned above, the “L”-shaped oxide layer 115 can be a silicon oxide layer, and the “L”-shaped nitride layer 125 can be a silicon nitride layer.

If the first nitride layer 120 is substituted with an oxynitride layer, the “L”-shaped nitride layer 125 can be replaced with an “L”-shaped oxynitride layer.

For NMOS devices with n-type channel, the stress film 170 may be a tensile stress film. For PMOS devices with P-type channel, the stress film 170 may be a compressive stress film.

During the formation of the device, the remaining portion 145 of the second nitride layer 140 serves as a block in source-drain implantation to define a heavily doped region.

Since the remaining portion 145 of the second nitride layer 140 is removed before silicide formation, it is unnecessary to remove nitride after silicide formation, avoiding the loss of silicide accordingly.

When etching to remove the remaining portion 145 of the second nitride layer 140, the remaining portion 135 of the second oxide layer 130 serves as an etch block layer to preserve the remaining portion 125 of the first nitride layer 120 (“L”-shaped nitride layer) and the remaining portion 115 of the first oxide layer 110 (“L”-shaped oxide layer).

A certain distance between the silicide 160 formed on the source and drain regions and the channel is generated due to the presence of the “L”-shaped nitride layer 125 and the “L”-shaped oxide layer 115, avoiding shorting the silicide 160 to the channel.

The preferable embodiment of this invention has been described in detail above, wherein, first, a stack 105 is formed including the first oxide layer 110, the first nitride layer 120, the second oxide layer 130 and second nitride layer 140.

However, from the analysis of the functions of those layers, the effect of this invention can be achieved by merely forming three layers (which can be referred to as “the first material layer”, “the second material layer”, and “the third material layer” from inner to outer).

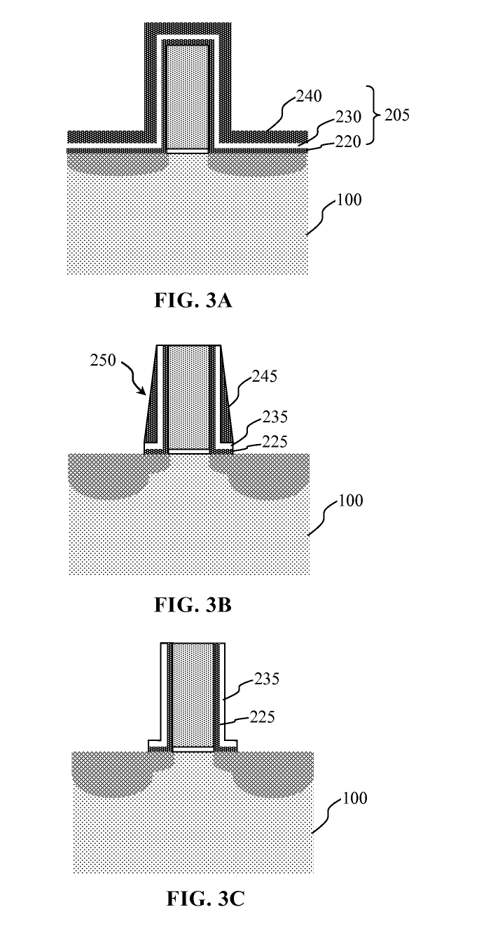

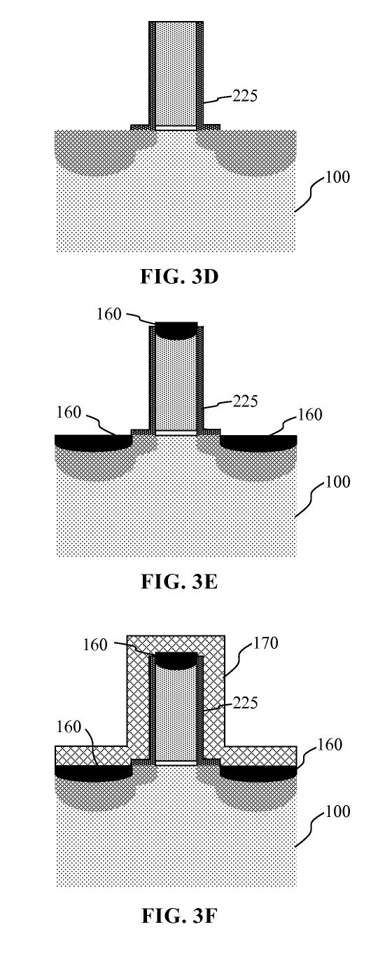

Below, another implementation of manufacturing semiconductor device with a three-layer stack will be described with reference to FIGS. 3A-3F.

First, as shown in FIG. 3A, a gate is formed on a substrate 100, which may comprise Si, and preferably have a (100) crystal plane. The gate is adjacent to the channel region, for example, it can be located above the channel region. Upon the implantation of lightly doped region (LDD) using the gate as a mask, a first material layer 220, a second material layer 230, and a third material layer 240 are deposited in sequence to form a stack 205. The stack 205 covers the surface of the substrate 100, the top surface of the gate, and opposite sidewalls of the gate.

The third material layer 240 can be relatively thicker, and the first material layer 220 and the second material layer 230 can be relatively thinner. The second material layer 230 can be a silicon oxide layer, and the first material layer 220 and the third material layer 240 can be silicon nitride layers.

Either or both of the first material layer 220 and the third material layer 240 can also be substituted with an oxynitride layer, for example, silicon oxynitride layer.

Next, as shown in FIG. 3B, the stack 205 is etched to form sidewall spacers 250 on opposite sidewalls of the gate. The sidewall spacers 250 comprises the remaining portion 225 of the first material layer 220, the remaining portion 235 of the second material layer 230, and the remaining portion 245 of the third material layer 240. Then, ion implantation is performed to form source region and drain region on opposite sides of the gate respectively.

Next, as shown in FIG. 3C, all or a portion of the remaining portion 245 of the third material layer 240 is removed through a wet or dry etching process with a high selectivity ratio to the remaining portion 235 of the second material layer 230. By doing so, the remaining portion 235 of the second material layer 230 serves as a block layer to prevent the remaining portion 225 of the first material layer 220 from being removed.

Next, as shown in FIG. 3D, a pre-cleaning process is performed before silicide formation. In the pre-cleaning process, the oxides on the surfaces of the source region, the drain region and the gate are removed. Meanwhile, all or a portion of the remaining portion 235 of the second material layer 230 is also removed.

The remaining portion 225 of the first material layer 220 is not removed in the pre-cleaning process.

Next, as shown in FIG. 3E, silicide 160 are formed on top of the source region, the drain region and gate. For example, a metal such as Ni or Pt is deposited on the source region, the drain region and gate. And then, a silicide forming process is performed to form metal silicides.

Next, as shown in FIG. 3F, a stress film 170 is deposited to cover the silicide 160 and the remaining portion 225 of the first material layer 220.

For a NMOS device region with n-type channel, a tensile stress film is deposited, and for a PMOS device region with p-type channel, a compressive stress film is deposited.

As an example of the stress film, a Si₃N₄ film deposited through thermal chemical vapor deposition can be utilized as the tensile stress film, and a Si₃N₄ film deposited through plasma chemical vapor deposition can be utilized as the compressive stress film.

As shown in FIG. 3F, the semiconductor device manufactured by the method of such an implementation comprises: a gate on a substrate; a source region and a drain region respectively on opposite sides of the gate; silicide 160 on top of the source region, the drain region and gate; an “L”-shaped first material layer 225 extending between the gate and the silicide 160 on top of the source region, between the gate and the silicide 160 on top of the drain region, and on the gate sidewalls; and a stress film 170 covering the silicide 160 and the “L”-shaped first material layer 225. As compared to the oxides, the first material has a lower selectivity ratio than an oxide in the pre-cleaning operation prior to the silicide formation process such that the “L”-shaped first material layer 225 can be retained while removing the exposed oxides. For example, the first material can be silicon nitride or silicon oxynitride.

As compared to the semiconductor device shown in FIG. 3, the semiconductor device shown in FIG. 2F is further provided with an “L”-shaped silicon oxide layer extending between the “L”-shaped first material layer and the substrate, and between the “L”-shaped first material layer and the gate sidewalls.

In this embodiment, upon etching to form the sidewall spacers including the remaining portions of the first material layer, the second material layer, and the third material layer, the remaining portion of the third material layer is used to define the heavily doped region in source-drain ion implantation.

When etching to remove the remaining portion of the third material layer, the remaining portion of the second material layer serves as a block layer, to preserve the remaining portion of the first material layer beneath.

The first and second material layers have different properties, in the pre-cleaning performance and the like, the first and second material layers have different selectivity ratios, so that the remaining portion of the first material layer can be retained while partially or completely removing the remaining portion of the second material layer. The remaining portion of the first material layer defines the areas of forming silicide on source region and drain region, ensuring a certain distance between the channel region and the silicide on source region and drain region, accordingly, avoiding the risk of shorting the silicide to the channel region.

It can be seen that forming the aforementioned stack including the first material layer, second material layer, and third material layer can achieve the effect of this invention. In addition, other material layers can be added as required.

Also, the first material layer, second material layer, and third material layer are not limited to the specific embodiments exemplified above, so long as they can function as above described respectively.

Further, the thickness of the third material layer can be determined by the thickness designation of the sidewall spacers. The second and first material layers can be thin to such an extent that it is sufficient to stop the etching process when an upper layer is removed. In this way, upon removing the third material layer finally, the distance between the deposited film and the channel region can be considerably reduced.

Hence, the present invention provides a method of manufacturing semiconductor device, which comprises the following steps: forming a gate on a substrate; forming a stack including a first material layer, a second material layer, and a third material layer from inner to outer in sequence, to cover the surface of the substrate, the top surface of the gate, and opposite sidewalls of the gate; etching the stack to form sidewall spacers on opposite sides of the gate, including the remaining portions of the first material layer, the second material layer and the third material layer; performing ion implantation to form a source region and a drain region on opposite sides of the gate respectively; partially or completely removing the remaining portion of the third material layer; performing a pre-cleaning process, wherein all or a portion of the remaining portion of the second material layer is removed; forming silicide on top of the source region, the drain region and the gate; depositing a stress film to cover the silicide and the remaining portion of the first material layer.

Thus, the method of manufacturing semiconductor device as well as the semiconductor device formed by such a method have been described in detail according to this invention. Some details that are well known in the art are not described for the purpose of not obscuring the concept of this invention. With the above description, those skilled in the art can thoroughly understand how to implement the technique solutions disclosed herein.

The above statement is given merely for illustration and description, and is not exhaustive, or to limit the invention to the disclosed form. Many modifications and changes are obvious to those skilled in the art. Embodiments are selected and described for a better illustration of the principle and practical application of this invention, so that those skilled in the art can understand this invention and envisage various embodiments with various modifications suited to specific usages.

What is claimed is:

1. A method of manufacturing a semiconductor device, comprising:
forming a gate on a substrate;
forming a stack including a first material layer, a second material layer, and a third material layer from inside to outside in sequence to cover the surface of the substrate, the top surface of the gate, and opposite sidewalls of the gate;
etching the stack to form sidewall spacers on opposite sidewalls of the gate, said sidewall spacers including the remaining portions of the first material layer, the second material layer and the third material layer;
performing ion implantation to form a source region and a drain region on opposite sides of the gate respectively;
partially or completely removing the remaining portion of the third material layer;
performing a pre-cleaning process, wherein all or a portion of the remaining portion of the second material layer is removed;
forming silicide on top of the source region, the drain region, and the gate;
depositing a stress film to cover the silicide and the remaining portion of the first material layer.

2. The method according to claim 1, wherein the remaining portion of the second material layer serves as a block layer when partially or completely removing the remaining portion of the third material layer.

3. The method according to claim 2, wherein the remaining portion of the third material layer is partially or completely removed through a wet or dry etching process with a high selectivity ratio to the second material layer.

4. The method according to claim 1, wherein the first material layer and the third material layer are silicon nitride layers or silicon oxynitride layers, and the second material layer is a silicon oxide layer.

5. The method according to claim 1, wherein the stack further comprises an oxide layer under the first material layer;
the sidewall spacers further comprises a remaining portion of the oxide layer; and
when performing the pre-cleaning process, the remaining portion of the first material layer serves as a block layer to prevent the oxide layer from being removed.

6. The method according to claim 5, wherein the oxide layer is a silicon oxide layer.

7. The method according to claim 1, wherein the gate is adjacent to a channel region, and when the channel region is an n-type channel region, the stress film is a tensile stress film.

8. The method according to claim 1, wherein the gate is adjacent to a channel region, and when the channel region is a p-type channel region, the stress film is a compressive stress film.

9. A semiconductor device, comprising:
a gate on a substrate;
a source region and a drain region respectively on opposite sides of the gate;
silicide on top of the source region, the drain region, and gate;
an “L”-shaped first material layer located between the gate and the silicide on top of the source region, between the gate and the silicide on top of the drain region, and on sidewalls of the gate, the first material having a lower selectivity ratio than an oxide in a pre-cleaning operation prior to the silicide forming process; and
a stress film covering the silicide and the “L”-shaped first material layer.

10. The semiconductor device according to claim 9, wherein the first material is silicon nitride or silicon oxynitride.

11. The semiconductor device according to claim 9, further comprising an “L”-shaped silicon oxide layer located between the “L”-shaped first material layer and the substrate, and between the “L”-shaped first material layer and the sidewalls of the gate.

12. The semiconductor device according to claim 9, wherein the gate is adjacent to a channel region, and when the channel region is an n-type channel region, the stress film is a tensile stress film.

13. The semiconductor device according to claim 9, wherein the gate is adjacent to a channel region, and when the channel region is a p-type channel region, the stress film is a compressive stress film.
